(19) United States
(12) Patent Application Publication
(10) Pub. No.: US 2023/0352631 A1
(43) Pub. Date: Nov. 2, 2023

(54) SEMICONDUCTOR LIGHT-EMITTING ELEMENT AND METHOD OF MANUFACTURING SEMICONDUCTOR LIGHT-EMITTING ELEMENT

(71) Applicant: NIKKISO CO., LTD., Tokyo (JP)

(72) Inventors: Noritaka NIWA, Ishikawa (JP); Tetsuhiko INAZU, Ishikawa (JP)

(21) Appl. No.: 18/141,312

(22) Filed: Apr. 28, 2023

(30) Foreign Application Priority Data
Apr. 28, 2022 (JP) 2022-074302

(51) Int. Cl. H01L 33/44; H01L 33/32; H01L 33/00; H01L 33/38

(52) U.S. Cl. CPC H01L 33/44; H01L 33/32; H01L 33/007; H01L 33/38

(57) ABSTRACT

A semiconductor light-emitting element includes: a first protective layer made of SiO₂ and a second protective layer made of SiNₓ. The first protective layer covers the n-type semiconductor layer, the active layer, the p-type semiconductor layer, the p-side contact electrode, the n-side contact electrode, the p-side current diffusion layer, and the n-side current diffusion layer in portions different from portions of the first p-side pad opening and the first n-side pad opening. The second protective layer covers the first protective layer in a portion different from portions of the second p-side pad opening and the second n-side pad opening, covers an inner circumferential surface of the first protective layer that defines the first p-side pad opening, and covers an inner circumferential surface of the first protective layer that defines the first n-side pad opening.

### RELATED APPLICATION

Priority is claimed to Japanese Patent Application No. 2022-074302, filed on Apr. 28, 2022, the entire content of which is incorporated herein by reference.

### BACKGROUND OF THE INVENTION

### 1. Field of the Invention

The present invention relates to a semiconductor light-emitting element and a method of manufacturing a semiconductor light-emitting element.

### 2. Description of the Related Art

A semiconductor light-emitting element includes an n-type semiconductor layer, an active layer, and a p-type semiconductor layer stacked on a substrate. An n-side electrode is provided on the n-type semiconductor layer, and a p-side electrode is provided on the p-type semiconductor layer. A covering layer made of a dielectric material such as SiO₂, Al₂O₃, and SiN is provided on the surface of the semiconductor light-emitting element (see, for example, JP2020-113741).

In order to further improve the reliability of a semiconductor light-emitting element, it is preferred to provide a protective layer having more excellent moisture resistance.

### SUMMARY OF THE INVENTION

The present invention addresses the issue described above, and a purpose thereof is to provide a technology for improving the reliability of a semiconductor light-emitting element.

A semiconductor light-emitting element according to an embodiment of the present invention includes: a base layer; an n-type semiconductor layer provided on the base layer and made of an n-type AlGaN-based semiconductor material; an active layer provided on the n-type semiconductor layer and made of an AlGaN-based semiconductor material; a p-type semiconductor layer provided on the active layer; an p-side contact electrode that is in contact with an upper surface of the p-type semiconductor layer; an n-side contact electrode that is in contact with an upper surface of the n-type semiconductor layer; a p-side current diffusion layer provided on the p-side contact electrode; an n-side current diffusion layer provided on the n-side contact electrode; a first protective layer including a first p-side pad opening provided on the p-side current diffusion layer and a first n-side pad opening provided on the n-side current diffusion layer, the first protective layer covering the n-type semiconductor layer, the active layer, the p-type semiconductor layer, the p-side contact electrode, the n-side contact electrode, the p-side current diffusion layer, and the n-side current diffusion layer in portions different from portions of the first p-side pad opening and the first n-side pad opening, and the first protective layer being made of silicon oxide; a second protective layer including a second p-side pad opening provided on the p-side current diffusion layer and a second n-side pad opening provided on the n-side current diffusion layer, the second protective layer covering the first protective layer in a portion different from portions of the second p-side pad opening and the second n-side pad opening, the second protective layer covering an inner circumferential surface of the first protective layer that defines the first p-side pad opening, covering an inner circumferential surface of the first protective layer that defines the first n-side pad opening, and the second protective layer being made of silicon nitride; a p-side pad electrode connected to the p-side current diffusion layer in the second p-side pad opening and overlapping the second protective layer outside the second p-side pad opening; and an n-side pad electrode connected to the n-side current diffusion layer in the second n-side pad opening and overlapping the second protective layer outside the second n-side pad opening.

Another aspect of the present invention relates to a method of manufacturing a semiconductor light-emitting element. The method includes: forming an n-type semiconductor layer made of an n-type AlGaN-based semiconductor material on a base layer; forming an active layer made of an AlGaN-based semiconductor material on the n-type semiconductor layer; forming a p-type semiconductor layer on the active layer; removing each of the p-type semiconductor layer and the active layer in part to expose an upper surface of the n-type semiconductor layer; forming a A-side contact electrode in contact with an upper surface of the p-type semiconductor layer; forming an n-side contact electrode in contact with an upper surface of the n-type semiconductor layer; forming a p-side current diffusion layer on the p-side contact electrode; forming an n-side current diffusion layer on the n-side contact electrode; forming a first protective layer that covers the n-type semiconductor layer, the active layer, the p-type semiconductor layer, the p-side contact electrode, the n-side contact electrode, the p-side current diffusion layer, and the n-side current diffusion layer and that is made of silicon oxide; removing the first protective layer on the p-side current diffusion layer to form a first p-side pad opening; removing the first protective layer on the n-side current diffusion layer to form a first n-side pad opening; forming a second protective layer that covers the first protective layer, that covers an inner circumferential surface of the first protective layer that defines the first p-side pad opening, covers an inner circumferential surface of the first protective layer that defines the first n-side pad opening, and that is made of silicon nitride; removing the second protective layer on the p-side current diffusion layer to form a second p-side pad opening; removing the second protective layer on the n-side current diffusion layer to form a second n-side pad opening; forming a p-side pad electrode connected to the p-side current diffusion layer in the second p-side pad opening and overlapping the second protective layer outside the second A-side pad opening; and forming an n-side pad electrode connected to the n-side current diffusion layer in the second n-side pad opening and overlapping the second protective layer outside the second n-side pad opening.

### BRIEF DESCRIPTION OF THE DRAWINGS

FIG. 1 is a cross sectional view schematically showing a configuration of a semiconductor light-emitting element according to the first embodiment;

FIG. 2 schematically shows a step of manufacturing the semiconductor light-emitting element according to the first embodiment;

FIG. 3 schematically shows a step of manufacturing the semiconductor light-emitting element according to the first embodiment;

FIG. 4 schematically shows a step of manufacturing the semiconductor light-emitting element according to the first embodiment;

FIG. 5 schematically shows a step of manufacturing the semiconductor light-emitting element according to the first embodiment;

FIG. 6 schematically shows a step of manufacturing the semiconductor light-emitting element according to the first embodiment;

FIG. 7 schematically shows a step of manufacturing the semiconductor light-emitting element according to the first embodiment;

FIG. 8 schematically shows a step of manufacturing the semiconductor light-emitting element according to the first embodiment;

FIG. 9 schematically shows a step of manufacturing the semiconductor light-emitting element according to the first embodiment;

FIG. 10 is a cross sectional view schematically showing a configuration of a semiconductor light-emitting device according to the first embodiment;

FIG. 11 is a cross sectional view schematically showing a configuration of a semiconductor light-emitting element according to the second embodiment;

FIG. 12 schematically shows a step of manufacturing the semiconductor light-emitting element according to the second embodiment;

FIG. 13 schematically shows a step of manufacturing the semiconductor light-emitting element according to the second embodiment;

FIG. 14 schematically shows a step of manufacturing the semiconductor light-emitting element according to the second embodiment;

FIG. 15 schematically shows a step of manufacturing the semiconductor light-emitting element according to the second embodiment;

FIG. 16 schematically shows a step of manufacturing the semiconductor light-emitting element according to the second embodiment;

FIG. 17 schematically shows a step of manufacturing the semiconductor light-emitting element according to the second embodiment;

FIG. 18 schematically shows a step of manufacturing the semiconductor light-emitting element according to the second embodiment;

FIG. 19 schematically shows a step of manufacturing the semiconductor light-emitting element according to the second embodiment;

FIG. 20 is a cross sectional view schematically showing a configuration of a semiconductor light-emitting element according to the third embodiment;

FIG. 21 schematically shows a step of manufacturing the semiconductor light-emitting element according to the third embodiment;

FIG. 22 schematically shows a step of manufacturing the semiconductor light-emitting element according to the third embodiment;

FIG. 23 schematically shows a step of manufacturing the semiconductor light-emitting element according to the third embodiment;

FIG. 24 schematically shows a step of manufacturing the semiconductor light-emitting element according to the third embodiment;

FIG. 25 schematically shows a step of manufacturing the semiconductor light-emitting element according to the third embodiment;

FIG. 26 schematically shows a step of manufacturing the semiconductor light-emitting element according to the third embodiment; and

FIG. 27 schematically shows a step of manufacturing the semiconductor light-emitting element according to the third embodiment.

### DETAILED DESCRIPTION OF THE INVENTION

The invention will now be described by reference to the preferred embodiments. This does not intend to limit the scope of the present invention, but to exemplify the invention.

A description will be given of an embodiment of the present invention with reference to the drawings. The numerals are used in the description to denote the same elements and a duplicate description is omitted as appropriate. To facilitate the understanding, the relative dimensions of the constituting elements in the drawings do not necessarily mirror the relative dimensions in the light-emitting element.

The semiconductor light-emitting element according to the embodiments is configured to emit “deep ultraviolet light” having a central wavelength λ of about 360 nm or shorter and is a so-called deep ultraviolet-light emitting diode (DUV-LED) chip. To output deep ultraviolet light having such a wavelength, an aluminum gallium nitride (AlGaN)-based semiconductor material having a band gap approximately equal to or more than 3.4 eV is used. The embodiments particularly show a case of emitting deep ultraviolet light having a central wavelength λ of about 240 nm-320 nm.

In this specification, the term “AlGaN-based semiconductor material” refers to a semiconductor material containing at least aluminum nitride (AlN) and gallium nitride (GaN) and shall encompass a semiconductor material containing other materials such as indium nitride (InN). Therefore, “AlGaN-based semiconductor materials” as recited in this specification can be represented by a composition In_{1-x-y}AlₓGa_{y}N (0<x+y≤1, 0<x<1, 0<y<1). The AlGaN-based semiconductor material shall encompass AlGaN or InAlGaN. The “AlGaN-based semiconductor material” in this specification has a molar fraction of AlN and a molar fraction of GaN equal to or more than 1%, and, preferably, equal to or more than 5%, equal to or more than 10%, or equal to or more than 20%.

Those materials that do not contain AlN may be distinguished by referring to them as “GaN-based semiconductor materials”. “GaN-based semiconductor materials” encompass GaN and InGaN. Similarly, those materials that do not contain GaN may be distinguished by referring to them as “AlN-based semiconductor materials”. “AlN-based semiconductor materials” encompass AlN and InAlN.

### First Embodiment

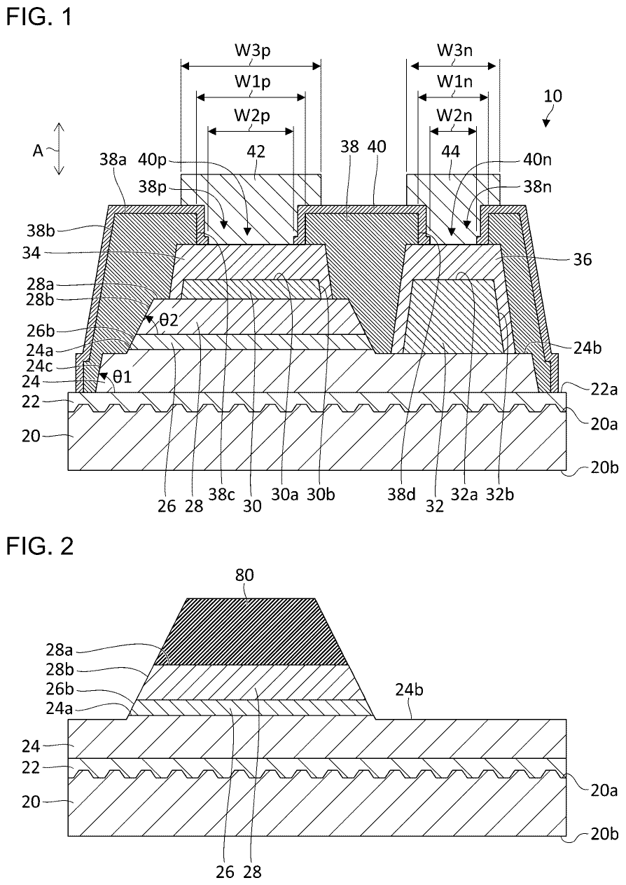

FIG. 1 is a cross sectional view schematically showing a configuration of a semiconductor light-emitting element 10 according to the first embodiment. The semiconductor light-emitting element 10 includes a substrate 20, a base layer 22, an n-type semiconductor layer 24, an active layer 26, a p-type semiconductor layer 28, a p-side contact electrode 30, an n-side contact electrode 32, a p-side current diffusion layer 34, an n-side current diffusion layer 36, a first protective layer 38, a second protective layer 40, a p-side pad electrode 42, and an n-side pad electrode 44.

Referring to FIG. 1, the direction indicated by the arrow A may be referred to as “vertical direction” or “direction of thickness”. Further, the direction away from the substrate 20 may be defined as “upward”, and the direction toward the substrate 20 may be defined as “downward”.

The substrate 20 includes a first principal surface 20a and a second principal surface 20b opposite to the first principal surface 20a. The first principal surface 20a is a crystal growth surface for growing the layers from the base layer 22 to the p-type semiconductor layer 28. The substrate 20 is made of a material having translucency for the deep ultraviolet light emitted by the semiconductor light-emitting element 10 and is made of, for example, sapphire (Al₂O₃). A fine concave-convex pattern having a submicron (1 μm or less) depth and pitch is formed on the first principal surface 20a. The substrate 20 like this is also called a patterned sapphire substrate (PSS). The second principal surface 20b is a light extraction substrate for extracting the deep ultraviolet light emitted by the active layer 26 outside. The substrate 20 may be made of AlN or made of AlGaN. The first principal surface 20a of the substrate 20 may be an ordinary substrate comprised of a flat surface that is not patterned.

The base layer 22 is provided on the first principal surface 20a of the substrate 20. The base layer 22 is a foundation layer (template layer) to form the n-type semiconductor layer 24. For example, the base layer 22 is an undoped AlN layer and is, specifically, an AlN layer gown at a high temperature (HT-AlN; High Temperature AlN). The base layer 22 may further include an undoped AlGaN layer formed on the AlN layer. The base layer 22 may be comprised only of an undoped AlGaN layer when the substrate 20 is an AlN substrate or an AlGaN substrate. In other words, the base layer 22 includes at least one of an undoped AlN layer or an undoped AlGaN layer.

The n-type semiconductor layer 24 is provided on an upper surface 22a of the base layer 22. The n-type semiconductor layer 24 is made of an n-type AlGaN-based semiconductor material. For example, the n-type semiconductor layer 24 is doped with Si as an n-type impurity. The composition ratio of the n-type semiconductor layer 24 is selected to transmit the deep ultraviolet light emitted by the active layer 26. For example, the n-type semiconductor layer 24 is formed such that the molar fraction of AlN is equal to or more than 25%, and, preferably, equal to or more than 40% or equal to or more than 50%. The n-type semiconductor layer 24 has a band gap larger than the wavelength of the deep ultraviolet light emitted by the active layer 26. For example, the n-type semiconductor layer 24 is formed to have a band gap equal to or more than 4.3 eV. It is preferable to form the n-type semiconductor layer 24 such that the molar fraction of AlN is equal to or less than 80%, i.e., the band gap is equal to or less than 5.5 eV. It is more desired to form the n-type semiconductor layer 24 such that the molar fraction of AlN is equal to or less than 70% (i.e., the band gap is equal to or less than 5.2 eV). The n-type semiconductor layer 24 has a thickness equal to or more than 1 μm and equal to or less than 3 μm. For example, the n-type semiconductor layer 24 has a thickness of about 2 μm.

The n-type semiconductor layer 24 is formed such that the concentration of Si as the impurity is equal to or more than 1×10¹⁸/cm³ and equal to or less than 5×10¹⁹/cm³. It is preferred to form the n-type semiconductor layer 24 such that the Si concentration is equal to or more than 5×10¹⁸/cm³ and equal to or less than 3×10¹⁹/cm³ and, more preferably, equal to or more than 7×10¹⁸/cm³ and equal to or less than 2×10¹⁹/cm³. In one example, the Si concentration in the n-type semiconductor layer 24 is around 1×10¹⁹/cm³ and, more specifically, is in a range equal to or more than 8×10¹⁸/cm³ and equal to or less than 1.5×10¹⁹/cm³.

The n-type semiconductor layer 24 includes a first upper surface 24a, a second upper surface 24b, and a side surface 24c. The first upper surface 24a is where the active layer 26 is formed, and the second upper surface 24b is where the active layer 26 is not formed. The side surface 24c is sloped with respect to the first upper surface 24a at a first angle θ1. The first angle θ1 is larger than 40° (i.e., does not include 40°) and equal to or smaller than 70°.

The active layer 26 is provided on the first upper surface 24a of the n-type semiconductor layer 24. The active layer 26 is made of an AlGaN-based semiconductor material and has a double heterojunction structure by being sandwiched between the n-type semiconductor layer 24 and the p-type semiconductor layer 28. To output deep ultraviolet light having a wavelength equal to or less than 355 nm, the active layer 26 is formed to have a band gap equal to or more than 3.4 eV. For example, the AlN composition ratio of the active layer 26 is selected so as to output deep ultraviolet light having a wavelength equal to or less than 320 nm.

For example, the active layer 26 has a monolayer or multilayer quantum well structure and is comprised of a barrier layer made of an undoped AlGaN-based semiconductor material and a well layer made of an undoped AlGaN-based semiconductor material. The active layer 26 includes, for example, a first barrier layer in contact with the n-type semiconductor layer 24 and a first well layer provided on the first barrier layer. One or more pairs of the barrier layer and the well layer may be additionally provided between the first well layer and the p-type semiconductor layer 28. Each of the barrier layer and the well layer has a thickness equal to or more than 1 nm and equal to or less than 20 nm, and has, for example, a thickness equal to or more than 2 nm and equal to or less than 10 nm. The active layer 26 has a side surface (or a sloped surface) sloped at a second angle 82. The second angle 82 is smaller than the first angle 81 and is equal to or smaller than 40°.

An electron block layer may further be provided between the active layer 26 and the p-type semiconductor layer 28. The electron block layer is made of an undoped AlGaN-based semiconductor material and is formed such that, for example, the molar fraction of AlN is equal to or more than 40%, and, preferably, equal to or more than 50%. The electron block layer may be formed such that the molar fraction of AlN is equal to or more than 80% or may be made of an AlN-based semiconductor material that does not contain GaN. The electron blocking layer has a thickness equal to or more than 1 nm and equal to or less than 10 nm. For example, the electron blocking layer has a thickness equal to or more than 2 nm and equal to or less than 5 nm. The electron block layer has a side surface (or a sloped surface) sloped at a second angle 82.

The p-type semiconductor layer 28 is formed on the active layer 26. The p-type semiconductor layer 28 is a p-type AlGaN-based semiconductor material layer or a p-type GaN-based semiconductor material layer. For example, the p-type semiconductor layer 28 is an AlGaN layer or a GaN layer doped with magnesium (Mg) as a p-type impurity. The p-type semiconductor layer 28 has, for example, a thickness equal to or more than 20 nm and equal to or less than 400 nm. The p-type semiconductor layer 28 has a side surface (or a sloped surface) sloped at a second angle 82.

The p-type semiconductor layer 28 may be comprised of a plurality of layers. The p-type semiconductor layer 28 may include, for example, a p-type clad layer and a p-type contact layer. The p-type clad layer is a p-type AlGaN layer having a relatively high AlN ratio as compared with the p-type contact layer and is provided to be in contact with the active layer 26. The p-type contact layer is a p-type AlGaN layer or a p-type GaN layer having a relatively low AlN ratio as compared with the p-type clad layer. The p-type contact layer is provided on the p-type clad layer and is provided to be in contact with the p-side contact electrode 30. The p-type clad layer may include a p-type first clad layer and a p-side second clad layer.

The composition ratio of the p-type first clad layer is selected to transmit the deep ultraviolet light emitted by the active layer 26. For example, the p-type first clad layer is formed such that the molar fraction of AlN is equal to or more than 25%, and, preferably, equal to or more than 40% or equal to or more than 50%. The AlN ratio of the p-type first clad layer is, for example, similar to the AlN ratio of the n-type semiconductor layer 24 or larger than the AlN ratio of the n-type semiconductor layer 24. The AlN ratio of the p-type clad layer may be equal to or more than 70% or equal to or more than 80%. The p-type first clad layer has a thickness equal to or more than 10 nm and equal to or less than 100 nm. For example, the p-type first clad layer has a thickness equal to or more than 15 nm and equal to or less than 70 nm.

The p-type second clad layer is provided on the p-type first clad layer. The p-type second clad layer is a p-type AlGaN layer having a medium AlN ratio and has an AlN ratio lower than that of the p-type first clad layer and higher than that of the p-type contact layer. For example, the p-type second clad layer is formed such that the molar fraction of AlN is equal to or more than 25%, and, preferably, equal to or more than 40% or equal to or more than 50%. The AlN ratio of the p-type second clad layer is configured to be, for example, about ±10% of the AlN ratio of the n-type semiconductor layer 24. The p-type second clad layer has a thickness equal to or more than 5 nm and equal to or less than 250 nm and has, for example, a thickness equal to or more than 10 nm and equal to or less than 150 nm. The p-type second clad layer may not be provided, and the p-type clad layer may be comprised only of the p-type first clad layer.

The p-type contact layer is a p-type AlGaN layer or a p-type GaN layer having a relatively low AlN ratio. The p-type contact layer is formed such that the AlN ratio is equal to or less than 20% in order to obtain proper ohmic contact with the p-side contact electrode 30. Preferably, the p-type contact layer is formed such that the AlN ratio is equal to or less than 10%, equal to or less than 5%, or 0%. In other words, the p-type contact layer may be made of a p-type GaN-based semiconductor material that does not substantially contain AlN. As a result, the p-type contact layer could absorb the deep ultraviolet light emitted by the active layer 26. It is preferred to form the p-type contact layer to be thin to reduce the quantity of absorption of the deep ultraviolet light emitted by the active layer 26. The p-type contact layer has a thickness equal to or more than 5 nm and equal to or less than 30 nm and has, for example, a thickness equal to or more than 10 nm and equal to or less than 20 nm.

The p-side contact electrode 30 is provided on an upper surface 28a of the p-type semiconductor layer 28. The p-side contact electrode 30 can be in ohmic contact with the p-type semiconductor layer 28 (for example, the p-type contact layer) and is made of a material having a high reflectivity for the deep ultraviolet light emitted by the active layer 26. The p-side contact electrode 30 includes an Rh layer in contact with the upper surface 28a of the p-type semiconductor layer 28. The p-side contact electrode 30 may be, for example, comprised only of the Rh layer. The thickness of the Rh layer included in the p-side contact electrode 30 is equal to or more than 50 nm and equal to or less than 200 nm and is, for example, equal to or more than 70 nm and equal to or less than 150 nm.

The n-side contact electrode 32 is provided on the second upper surface 24b of the n-type semiconductor layer 24. The n-side contact electrode 32 has, for example, a Ti/Al/Ti/TiN stack structure in which a first Ti layer, an Al layer, a second Ti layer, and a TiN layer are sequentially stacked. The first Ti layer of the n-side contact electrode 32 is in contact with the second upper surface 24b of the n-type semiconductor layer 24. The thickness of the first Ti layer of the n-side contact electrode 32 is equal to or more than 1 nm and equal to or less than 10 nm and, preferably, equal to or less than 5 nm or equal to or less than 2 nm. The Al layer of the n-side contact electrode 32 is provided on the first Ti layer and is fin contact with the first Ti layer. The thickness of the Al layer of the n-side contact electrode 32 is equal to or more than 200 nm and is, for example, equal to or more than 300 nm and equal to or less than 1000 nm. The second Ti layer of the n-side contact electrode 32 is provided on the Al layer and is in contact with the Al layer. The thickness of the second Ti layer of the n-side contact electrode 32 is equal to or more than 1 nm and equal to or less than 50 nm and is, for example, equal to or more than 5 nm and equal to or less than 25 nm. The TiN layer of the n-side contact electrode 32 is provided on the second Ti layer and is in contact with the second Ti layer. The TiN layer of the n-side contact electrode 32 is made of TiN having conductivity. The thickness of the TiN layer of the n-side contact electrode 32 is equal to or more than 5 nm and equal to or less than 100 nm and is, for example, equal to or more than 10 nm and equal to or less than 50 nm.

The p-side current diffusion layer 34 is provided to be in contact with an upper surface 30a and a side surface 30b of the p-side contact electrode 30 and to cover the entirety of the p-side contact electrode 30. The p-side current diffusion layer 34 has, for example, a TiN/Ti/Rh/TiN/Ti/Au stack structure in which a first TiN layer, a Ti layer, an Rh layer, a second TiN layer, a Ti layer, and an Au layer are sequentially stacked.

The first TiN layer and the second TiN layer of the p-side current diffusion layer 34 are made of TiN having conductivity. The thickness of each of the first TiN layer and the second TiN layer of the p-side current diffusion layer 34 is equal to or more than 10 nm and equal to or less than 200 nm and is, for example, equal to or more than 50 nm and equal to or less than 150 nm. The thickness of each of the Ti layer and the Rh layer provided between the first TiN layer and the second TiN layer of the p-side current diffusion layer 34 is equal to or more than 10 nm and equal to or less than 200 nm and is, for example, equal to or more than 20 nm and equal to or less than 150 nm. The p-side current diffusion layer 34 may include a plurality of Ti layers and a plurality of Rh layers that are alternately stacked between the first TiN layer and the second TiN layer. The thickness of the Ti layer provided on the second TiN layer of the p-side current diffusion layer 34 is equal to or more than 1 nm and equal to or less than 50 nm and is, for example, equal to or more than 5 nm and equal to or less than nm. The Au layer of the p-side current diffusion layer 34 equal to or more than 100 nm and equal to or less than 500 nm and is, for example, equal to or more than 150 nm and equal to or less than 300 nm.

The p-side current diffusion layer 34 is provided to cover an upper surface 32a and a side surface 32b of the n-side contact electrode 32. The n-side current diffusion layer 36 is configured similarly as the p-side current diffusion layer 34 and has, for example, a TiN/Ti/Rh/TiN/Ti/Au stack structure in which a first TiN layer, a Ti layer, an Rh layer, a second TiN layer, a Ti layer, and an Au layer are sequentially stacked.

The first TiN layer and the second TiN layer of the n-side current diffusion layer 36 are made of TiN having conductivity. The thickness of each of the first TiN layer and the second TiN layer of the n-side current diffusion layer 36 is equal to or more than 10 nm and equal to or less than 200 nm and is, for example, equal to or more than 50 nm and equal to or less than 150 nm. The thickness of each of the Ti layer and the Rh layer provided between the first TiN layer and the second TiN layer of the n-side current diffusion layer 36 is equal to or more than 10 nm and equal to or less than 200 nm and is, for example, equal to or more than 20 nm and equal to or less than 150 nm. The n-side current diffusion layer 36 may include a plurality of Ti layers and a plurality of Rh layers that are alternately stacked between the first TiN layer and the second TiN layer. The thickness of the Ti layer provided on the second TiN layer of the n-side current diffusion layer 36 is equal to or more than 1 nm and equal to or less than 50 nm and is, for example, equal to or more than 5 nm and equal to or less than nm. The Au layer of the n-side current diffusion layer 36 is equal to or more than 100 nm and equal to or less than 500 nm and is, for example, equal to or more than 150 nm and equal to or less than 300 nm.

The first protective layer 38 is provided to cover the entirety of the element from above. The first protective layer 38 covers the n-type semiconductor layer 24, the active layer 26, the p-type semiconductor layer 28, the p-side contact electrode 30, the n-side contact electrode 32, the p-side current diffusion layer 34, and the n-side current diffusion layer 36. The first protective layer 38 has a first p-side pad opening 38p provided on the p-side current diffusion layer 34 and a first n-side pad opening 38n provided on the n-side current diffusion layer 36. The first protective layer 38 covers the p-side current diffusion layer 34 in a portion different from that of the first p-side pad opening 38p and covers the n-side current diffusion layer 36 in a portion different from that of the first n-side pad opening 38n. The first protective layer 38 is in contact with the base layer 22 at the outer circumference of the n-type semiconductor layer 24. The first protective layer 38 is in contact with the upper surface 22a of the base layer 22, is in contact with the second upper surface 24b and the side surface 24c of the n-type semiconductor layer 24, is in contact with the side surface 26b of the active layer 26, is in contact with the upper surface 28a and the side surface 28b of the p-type semiconductor layer 28, is in contact with the p-side current diffusion layer 34, and is in contact with the n-side current diffusion layer 36.

The first protective layer 38 is made of an oxide dielectric material such as silicon oxide (SiO₂), aluminum oxide (Al₂O₃), and hafnium oxide (HfO₂). The first protective layer 38 is preferably made of SiO₂. The thickness of the first protective layer 38 is equal to or more than 300 nm and equal to or less than 1500 nm and is, for example, equal to more than 600 nm and equal to or less than 1000 nm.

The second protective layer 40 is provided to cover the entirety of the element from above and is provided to cover the entirety of the surface of the first protective layer 38. The second protective layer 40 has a second p-side pad opening 40p provided on the p-side current diffusion layer 34 and a second n-side pad opening 40n provided on the n-side current diffusion layer 36. The second protective layer 40 covers the first protective layer 38 in a portion different from portions of the second p-side pad opening 40p and the second n-side pad opening 40n. The second protective layer 40 is also provided inside each of the first p-side pad opening 38p and the first n-side pad opening 38n. The second protective layer 40 covers an inner circumferential surface 38c of the first protective layer 38 that defines the first p-side pad opening 38p and covers an inner circumferential surface 38d of the first protective layer 38 that defines the first n-side pad opening 38n. A range W2p in which the second p-side pad opening 40p is formed is smaller than a range W1p in which the first p-side pad opening 38p is formed and is inside the range W1p in which the first p-side pad opening 38p is formed. A range W2n in which the second n-side pad opening 40n is formed is smaller than a range W1n in which the first n-side pad opening 38n is formed and is inside the range W1n in which the first n-side pad opening 38n is formed. The second protective layer 40 is in contact with the base layer 22 at the outer circumference of the first protective layer 38. The second protective layer 40 is in contact with the upper surface 22a of the base layer 22, is in contact with the upper surface 38a and the side surface 38b of the first protective layer 38, is in contact with the inner circumferential surfaces 38c, 38d of the first protective layer 38, is in contact with the p-side current diffusion layer 34, and is in contact with the n-side current diffusion layer 36.

The second protective layer 40 is made of silicon nitride (SiNₓ), which is a dielectric material having high moisture resistance. The thickness of the second protective layer 40 is equal to or more than 50 nm and equal to or less than 500 nm and is, for example, equal to more than 100 nm and equal to or less than 400 nm.

The p-side pad electrode 42 and the n-side pad electrode 44 are portions bonded when the semiconductor light-emitting element 10 is mounted on a submount substrate or the like. The p-side pad electrode 42 and the n-side pad electrode 44 include, for example, a Ni/Au, Ti/Au, or Ti/Pt/Au stack structure. The thickness of each of the A-side pad electrode 42 and the n-side pad electrode 44 is equal to or more than 100 nm and is, for example, equal to or more than 200 nm and equal to or less than 1000 nm.

The p-side pad electrode 42 is provided on the p-side current diffusion layer 34 and is connected to the A-side current diffusion layer 34 in the second p-side pad opening 40p. The p-side pad electrode 42 is provided to block the second p-side pad opening 40p and overlaps the second protective layer 40 outside the second p-side pad opening 40p. A range W3p in which the p-side pad electrode 42 is formed is larger than a range W2p in which the second p-side pad opening 40p is formed. The p-side pad electrode 42 may overlap the first protective layer 38 outside the first p-side pad opening 38p. The range W3p in which the A-side pad electrode 42 is formed may be larger than the range W1p in which the first p-side pad opening 38p is formed. The p-side pad electrode 42 is electrically connected to the A-side contact electrode 30 via the p-side current diffusion layer 34.

The n-side pad electrode 44 is provided on the n-side current diffusion layer 36 and is connected to the n-side current diffusion layer 36 in the second n-side pad opening 40n. The n-side pad electrode 44 is provided to block the second n-side pad opening 40n and overlaps the second protective layer 40 outside the second n-side pad opening 40n. A range W3n in which the n-side pad electrode 44 is formed is larger than a range W2n in which the second n-side pad opening 40n is formed. The n-side pad electrode 44 may overlap the first protective layer 38 outside the first n-side pad opening 38n. The range W3n in which the n-side pad electrode 44 is formed may be larger than the range W1n in which the first n-side pad opening 38n is formed. The n-side pad electrode 44 is electrically connected to the n-side contact electrode 32 via the n-side current diffusion layer 36.

A description will now be given of a method of manufacturing the semiconductor light-emitting element 10 according to the first embodiment. FIGS. 2-9 schematically show steps of manufacturing the semiconductor light-emitting element 10 according to the first embodiment. First, referring to FIG. 2, the base layer 22, the n-type semiconductor layer 24, the active layer 26, and the p-type semiconductor layer 28 are formed on the first principal surface 20a of the substrate 20 sequentially.

The substrate 20 is, for example, a patterned sapphire substrate. The base layer 22 includes, for example, an HT-AlN layer and an undoped AlGaN layer. The n-type semiconductor layer 24, the active layer 26, and the p-type semiconductor layer 28 are semiconductor layers made of an AlGaN-based semiconductor material, an AlN-based semiconductor material, or a GaN-based semiconductor material and can be formed by a well-known epitaxial growth method such as the metal organic vapor phase epitaxy (MOVPE) method and the molecular beam epitaxy (MBE) method.

Subsequently, as shown in FIG. 2, a mask 80 is formed on the upper surface 28a of the p-type semiconductor layer 28 by using, for example, a publicly known lithographic technology. The p-type semiconductor layer 28 and the active layer 26 in a region not overlapping the mask 80 are removed by dry-etching or the like while the mask 80 is formed, to expose the second upper surface 24b of the n-type semiconductor layer 24. This etching step forms the side surface 28b of the p-type semiconductor layer 28, the side surface 26b of the active layer 26, and the second upper surface 24b of the n-type semiconductor layer 24. The mask 80 is then removed.

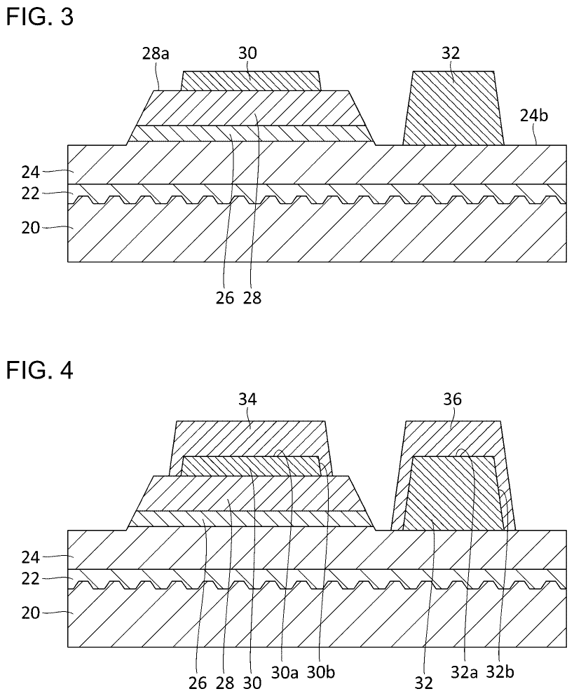

Subsequently, as shown in FIG. 3, the p-side contact electrode 30 is formed on the upper surface 28a of the p-type semiconductor layer 28 by using, for example, a publicly known lithographic technology. The p-side contact electrode 30 includes an Rh layer in contact with the upper surface 28a of the p-type semiconductor layer 28. The Rh layer of the p-side contact electrode 30 is formed by deposition at a temperature equal to or less than 100° C. By forming the Rh layer by deposition, the damage to the upper surface 28a of the p-type semiconductor layer 28 can be reduced and the contact resistance of the p-side contact electrode 30 can be improved as compared with the case of using sputtering.

After the p-side contact electrode 30 is formed, the p-side contact electrode 30 is annealed. The p-side contact electrode 30 is annealed by using, for example, the rapid thermal annealing (RTA) method at a temperature equal to or more than 500° C. and equal to or less than 650° C. The annealing process of the p-side contact electrode 30 lowers the contact resistance of the p-side contact electrode 30. The annealing process of the p-side contact electrode 30 increases the film density of the p-side contact electrode 30 and improves the reflectivity of the p-side contact electrode 30. The reflectivity of the Rh layer of the p-side contact electrode 30 for the wavelength 280 nm after the annealing process is equal to or more than 65% and is, for example, 67%.

Subsequently, as shown in FIG. 3, the n-side contact electrode 32 is formed on the second upper surface 24b of the n-type semiconductor layer 24 by using, for example, a publicly known lithographic technology. The n-side contact electrode 32 is in contact with the second upper surface 24b of the n-type semiconductor layer 24 and includes a first Ti layer, an Al layer, a second Ti layer, and a TiN layer stacked sequentially. The first Ti layer, the Al layer, the second Ti layer, and the TiN layer forming the n-side contact electrode 32 can be formed by sputtering.

After the n-side contact electrode 32 is formed, the n-side contact electrode 32 is annealed. The n-side contact electrode 32 is annealed by using, for example, the RTA method at a temperature equal to or more than 500° C. and equal to or less than 650° C. The annealing process of the n-side contact electrode 32 lowers the contact resistance of the n-side contact electrode 32.

Subsequently, as shown in FIG. 4, the p-side current diffusion layer 34 is formed to cover the upper surface 30a and the side surface 30b of the p-side contact electrode 30, and the n-side current diffusion layer 36 is formed to cover the upper surface 32a and the side surface 32b of the n-side contact electrode 32, by using, for example, a publicly known lithographic technology. The A-side current diffusion layer 34 and the n-side current diffusion layer 36 include a first TiN layer, a Ti layer, an Rh layer, a second TiN layer, a Ti layer, and an Au layer stacked sequentially. The p-side current diffusion layer 34 and the n-side current diffusion layer 36 can be formed simultaneously by using sputtering at a temperature equal to or less than 100° C. The p-side current diffusion layer 34 and the n-side current diffusion layer 36 may be formed separately.

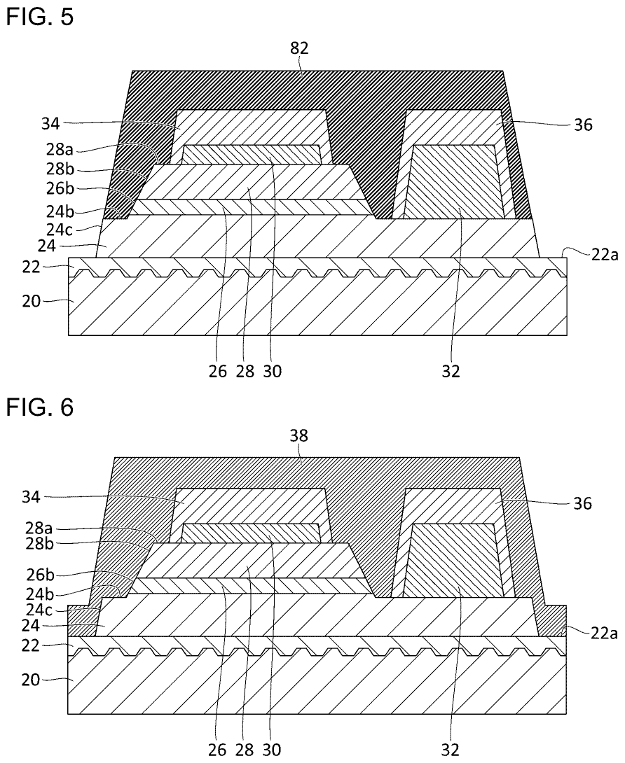

Subsequently, as shown in FIG. 5, a mask 82 is formed on the n-type semiconductor layer 24, the active layer 26, the p-type semiconductor layer 28, the p-side current diffusion layer 34, and the n-side current diffusion layer 36 by using, for example, a publicly known lithographic technology. The n-type semiconductor layer 24 in a region not overlapping the mask 82 is removed by dry-etching or the like while the mask 82 is formed to expose the upper surface 22a of the base layer 22. This etching step forms the side surface 24c of the n-type semiconductor layer 24. The mask 82 is then removed.

Subsequently, as shown in FIG. 6, the first protective layer 38 is formed to cover the entirety of the element from above. The first protective layer 38 can be made of SiO₂ and can be formed by plasma enhanced chemical vapor deposition (PECVD). The first protective layer 38 is formed to be in contact with and to cover the upper surface 22a of base layer 22, the second upper surface 24b and the side surface 24c of the n-type semiconductor layer 24, a side surface 26c of the active layer 26, the upper surface 28a and a side surface 28c of the p-type semiconductor layer 28, the p-side current diffusion layer 34, and the n-side current diffusion layer 36.

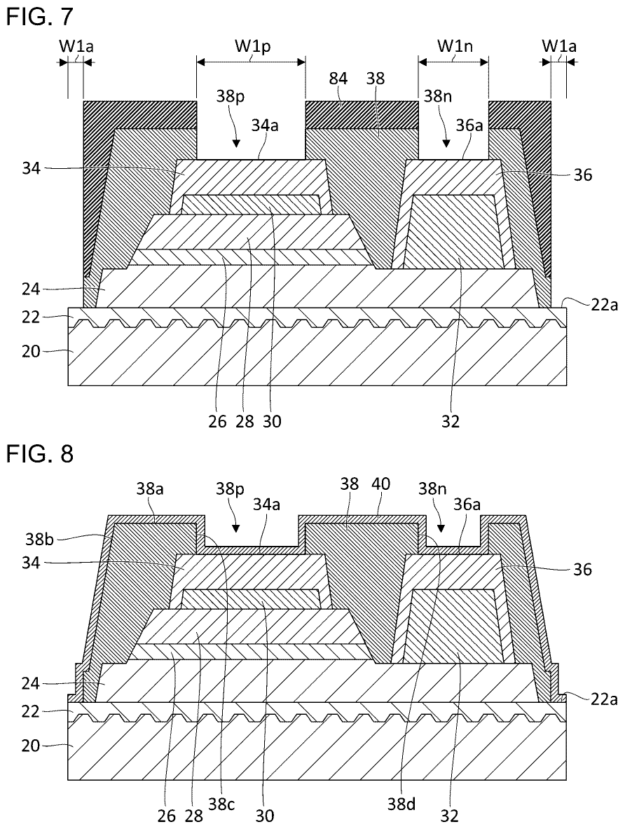

Subsequently, as shown in FIG. 7, a mask 84 is formed on the first protective layer 38 by using, for example, a publicly known lithographic technology. The mask 84 is formed to exclude the range W1p in which the first A-side pad opening 38p is formed, the range W1n in which the first n-side pad opening 38n is formed, and a first outer circumferential range W1a in which the upper surface 22a of the base layer 22 is exposed. The first protective layer 38 in a region not overlapping the mask 84 is removed by dry-etching or the like while the mask 84 is formed. The first p-side pad opening 38p in which an upper surface 34a of the p-side current diffusion layer 34 is exposed is formed by removing the first protective layer 38 on the p-side current diffusion layer 34. The first n-side pad opening 38n in which an upper surface 36a of the n-side current diffusion layer 36 is exposed is formed by removing the first protective layer 38 on the n-side current diffusion layer 36. Further, the upper surface 22a of the base layer 22 is exposed by removing the outer circumferential part of the first protective layer 38 in the first outer circumferential range W1a. The mask 84 is then removed.

Subsequently, as shown in FIG. 8, the second protective layer 40 is formed to cover the entirety of the element from above. The second protective layer 40 can be made of SiNₓ and can be formed by PECVD. The second protective layer 40 is formed to be in contact with and to cover the upper surface 22a of base layer 22 and the upper surface 38a and the side surface 38b of the first protective layer 38. In the first p-side pad opening 38p, the second protective layer 40 is in contact with and covers the inner circumferential surface 38c of the first protective layer 38 that defines the first p-side pad opening 38p and is in contact with and covers the upper surface 34a of the p-side current diffusion layer 34. In the first n-side pad opening 38n, the second protective layer 40 is in contact with and covers the inner circumferential surface 38d of the first protective layer 38 that defines the first n-side pad opening 38n and is in contact with and covers the upper surface 36a of the n-side current diffusion layer 36.

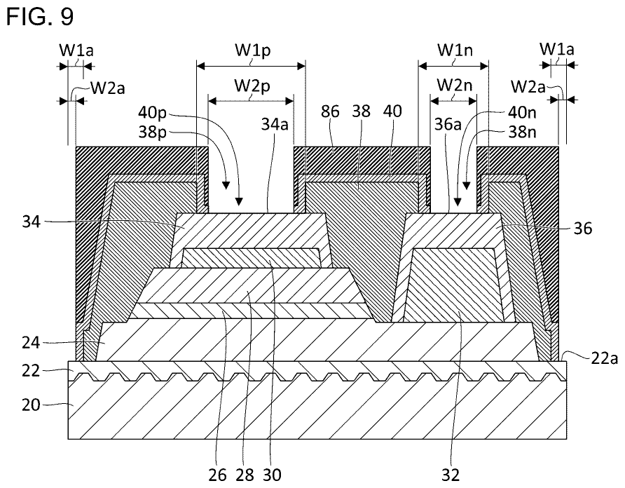

Subsequently, as shown in FIG. 9, a mask 86 is formed on the second protective layer 40 by using, for example, a publicly known lithographic technology. The mask 86 is formed to exclude the range W2p in which the second p-side pad opening 40p is formed, the range W2n in which the second n-side pad opening 40n is formed, and a second outer circumferential range W2a in which the upper surface 22a of the base layer 22 is exposed. The second protective layer 40 in a region not overlapping the mask 86 is removed by dry-etching or the like while the mask 86 is formed. The second p-side pad opening 40p in which an upper surface 34a of the p-side current diffusion layer 34 is exposed is formed by removing the second protective layer 40 on the p-side current diffusion layer 34. The second n-side pad opening 40n in which an upper surface 36a of the n-side current diffusion layer 36 is exposed is formed by removing the second protective layer 40 on the n-side current diffusion layer 36. Further, the upper surface 22a of the base layer 22 is exposed by removing the outer circumferential part of the second protective layer 40 in the second outer circumferential range W2a. The second outer circumferential range W2a will be an element separation area for cutting the substrate 20 and the base layer 22 to turn the element into individual pieces. The mask 86 is then removed.

Subsequently, as shown in FIG. 1, the p-side pad electrode 42 connected to the p-side current diffusion layer 34 in the second p-side pad opening 40p is formed, and the n-side pad electrode 44 connected to the n-side current diffusion layer 36 in the second n-side pad opening 40n is formed. The p-side pad electrode 42 is formed to overlap the second protective layer 40 outside the second p-side pad opening 40p. The n-side pad electrode 44 is formed to overlap the second protective layer 40 outside the second n-side pad opening 40n. The p-side pad electrode 42 and the n-side pad electrode 44 can be formed concurrently but can be formed separately.

The semiconductor light-emitting element 10 shown in FIG. 1 is completed through the steps described above.

According to this embodiment, the moisture resistance of the semiconductor light-emitting element 10 can be improved by combining the first protective layer 38 made of SiO₂ and the second protective layer 40 made of SiNₓ. Further, the moisture resistance of the semiconductor light-emitting element 10 can be further improved by covering the inner circumferential surfaces 38c, 38d of the first protective layer 38 that define the first p-side pad opening 38p and the first n-side pad opening 38n.

According to this embodiment, the moisture resistance of the semiconductor light-emitting element 10 can be further improved by covering the entirety of the side surface 38b of the first protective layer 38 by the second protective layer 40. In other words, causing the second protective layer 40 to be in contact with the base layer 22 prevents the first protective layer 38 from being exposed outside without being covered by the second protective layer at the outer circumference of the first protective layer 38.

According to this embodiment, each of the p-side pad electrode 42 and the n-side pad electrode 44 is in contact with the second protective layer 40 and is not in contact with the first protective layer 38 so that p-side pad electrode 42 and the n-side pad electrode 44 can be formed in portions where the second protective layer 40 overlaps the first protective layer 38. This can increase the quality of sealing in the portions where the p-side pad electrode 42 and the n-side pad electrode 44 are formed and further improve the moisture resistance of the semiconductor light-emitting element 10.

The semiconductor light-emitting element 10 according to this embodiment has excellent moisture resistance and so can be used without being sealed in a package. The semiconductor light-emitting element 10 can be energized for use in a condition in which the second protective layer 40 is exposed to an external environment. For example, the semiconductor light-emitting element 10 can be used in a chip on submount (CoS) mode.

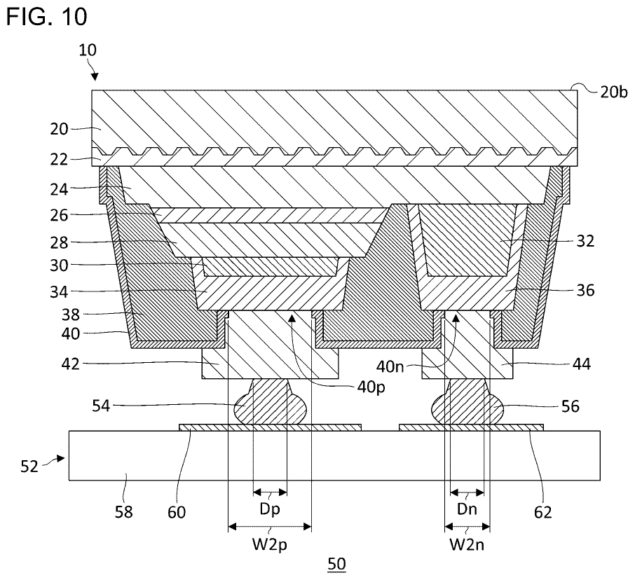

FIG. 10 is a cross-sectional view schematically showing a configuration of a semiconductor light-emitting device 50 according to the first embodiment. The semiconductor light-emitting device 50 includes the semiconductor light-emitting element 10, a submount 52, a first stud bump 54, and a second stud bump 56. The semiconductor light-emitting device 50 is a CoS type device. FIG. 10 shows the semiconductor light-emitting element 10 shown in FIG. 1 upside down.

The submount 52 includes a submount substrate 58, a first mount electrode 60, and a second mount electrode 62. The first mount electrode 60 and the second mount electrode 62 are provided on a surface 58a of the submount substrate 58. The first mount electrode 60 is connected to the p-side pad electrode 42 via the first stud bump 54. The second mount electrode 62 is connected to the n-side pad electrode 44 via the second stud bump 56.

The first stud bump 54 and the second stud bump 56 bond the semiconductor light-emitting element 10 and the submount 52. The first stud bump 54 and the second stud bump 56 are so-called Au stud bumps and can be formed by fusing the tip of an Au wire into a ball and thrusting the ball against the submount 52. The first stud bump 54 and the second stud bump 56 can be, for example, ultrasonically bonded to the p-side pad electrode 42 or the n-side pad electrode 44.

The range W2p in which the second p-side pad opening 40p is formed is larger than a range Dp occupied by the bonding portion of the p-side pad electrode 42 and the first stud bump 54 and larger than a diameter Dp at the bonding end of the first stud bump 54. This allows the first stud bump 54 to be bonded to the p-side pad electrode 42, ensuring that the bonding end of the first stud bump 54 does not overlap the second protective layer 40 in the direction of thickness. Similarly, the range W2n in which the second n-side pad opening 40n is formed is larger than a range Dn occupied by the bonding portion of the n-side pad electrode 44 and the second stud bump 56 and larger than a diameter Dn at the bonding end of the second stud bump 56. This allows the second stud bump 56 to be bonded to the n-side pad electrode 44, ensuring that the bonding end of the second stud bump 56 does not overlap the second protective layer 40 in the direction of thickness. As a result, a damage such as a crack in the second protective layer 40 can be prevented from occurring due to the load incurred when the first stud bump 54 and the second stud bump 56 are bonded, and the reliability of the semiconductor light-emitting element 10 can be improved.

### Second Embodiment

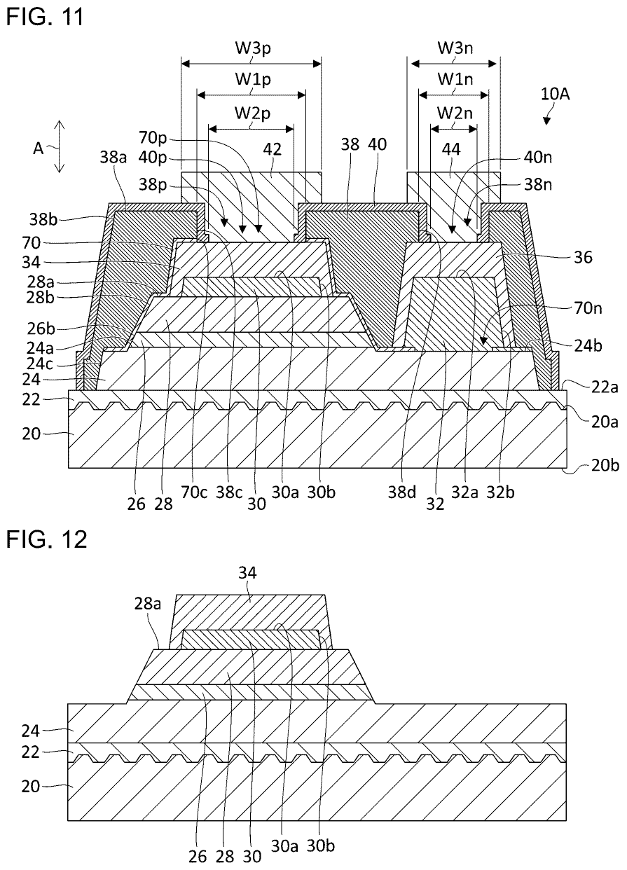

FIG. 11 is a cross-sectional view schematically showing a configuration of a semiconductor light-emitting element 10A according to the second embodiment. The second embodiment differs from the first embodiment described above in that the semiconductor light-emitting element 10A further includes a dielectric covering layer 70. The following description of the second embodiment highlights the difference from the first embodiment. A description of common features is omitted as appropriate.

The semiconductor light-emitting element 10A includes a substrate 20, a base layer 22, an n-type semiconductor layer 24, an active layer 26, a p-type semiconductor layer 28, a p-side contact electrode 30, an n-side contact electrode 32, a p-side current diffusion layer 34, an n-side current diffusion layer 36, a first protective layer 38, a second protective layer 40, a p-side pad electrode 42, an n-side pad electrode 44, and a dielectric covering layer 70.

The dielectric covering layer 70 is provided between each of the active layer 26 and the p-type semiconductor layer 28 and the first protective layer 38. The dielectric covering layer 70 is formed to be in contact with and to cover the n-type semiconductor layer 24, the active layer 26, the p-type semiconductor layer 28, and the p-side current diffusion layer 34. The dielectric covering layer 70 has a contact opening 70n provided on the second upper surface 24b of the n-type semiconductor layer 24 and covers the second upper surface 24b of the n-type semiconductor layer 24 in a portion different from that of the contact opening 70n. The dielectric covering layer 70 covers side surface 26b of the active layer 26 and the upper surface 28a and the side surface 28b of the p-type semiconductor layer 28. The dielectric covering layer 70 has a third p-side pad opening 70p provided on the p-side current diffusion layer 34 and covers the p-side current diffusion layer 34 in a portion different from that of the third p-side pad opening 70p. The range in which the third p-side pad opening 70p is formed is equal to the range W1p in which the first p-side pad opening 38p is formed. The range in which the third p-side pad opening 70p is formed is larger than the range W2p in which the second p-side pad opening 40p is formed.

The dielectric covering layer 70 is made of an oxide dielectric material such as SiO₂, Al₂O₃, and HfO₂ and is made of a material different from that of the first protective layer 38. The dielectric covering layer 70 is preferably made of Al₂O₃. The thickness of the dielectric covering layer 70 is equal to or more than 10 nm and equal to or less than 100 nm and is, for example, equal to or more than 20 nm and equal to or less than 50 nm.

The n-side contact electrode 32 is provided to block the contact opening 70n and overlaps the dielectric covering layer 70 outside the contact opening 70n. The n-side contact electrode 32 is in contact with the dielectric covering layer 70 outside the contact opening 70n. The range in which the n-side contact electrode 32 is formed is larger than a range in which the contact opening 70n is formed.

The n-side current diffusion layer 36 overlaps the dielectric covering layer 70 outside the contact opening 70n. The n-side current diffusion layer 36 is in contact with the dielectric covering layer 70 outside the n-side contact electrode 32. The range in which the n-side current diffusion layer 36 is formed is larger than the range in which the contact opening 70n is formed.

The first protective layer 38 is in contact with the dielectric covering layer 70. The first protective layer 38 covers the dielectric covering layer 70 in a portion different from that of the first p-side pad opening 38p. The second protective layer 40 further covers an inner circumferential surface 70c of the dielectric covering layer 70 that defines the third p-side pad opening 70p.

A description will now be given of a method of manufacturing the semiconductor light-emitting element 10A according to the second embodiment. First, the steps shown in FIG. 2 of the first embodiment are performed. Subsequently, the steps of FIGS. 12-19 are performed. FIGS. 12-19 schematically show steps of manufacturing the semiconductor light-emitting element 10A according to the second embodiment.

Following the steps of FIG. 2, the p-side contact electrode 30 is formed on the upper surface 28a of the p-type semiconductor layer 28 by using, for example, a publicly known lithographic technology. After the p-side contact electrode 30 is formed, the p-side contact electrode 30 is annealed. Subsequently, the p-side current diffusion layer 34 is formed to cover the upper surface 30a and the side surface 30b of the p-side contact electrode 30 by using, for example, a publicly known lithographic technology.

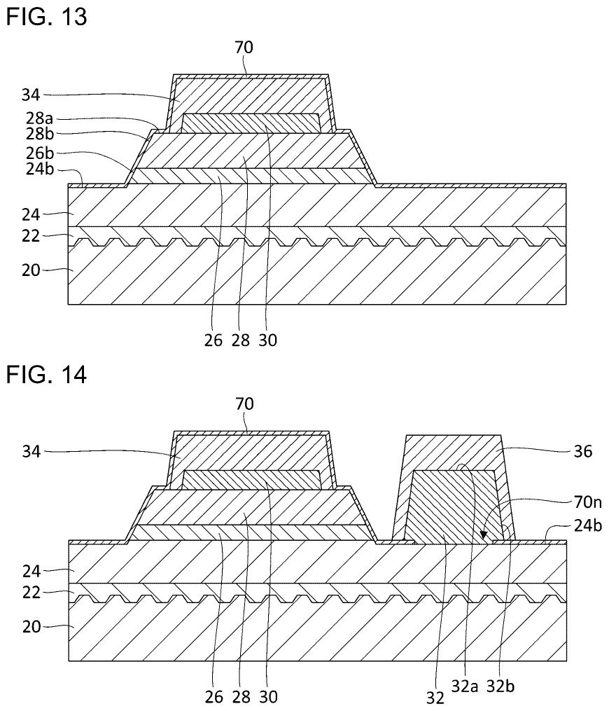

Subsequently, as shown in FIG. 13, the dielectric covering layer 70 is formed. The dielectric covering layer 70 is formed to be in contact with and to cover the second upper surface 24b of the n-type semiconductor layer 24, the side surface 26b of the active layer 26, the upper surface 28a and the side surface 28b of the p-type semiconductor layer 28, and the p-side current diffusion layer 34. The dielectric covering layer 70 can be made of Al₂O₃ and can be formed by atomic layer deposition (ALD).

Subsequently, as shown in FIG. 14, the dielectric covering layer 70 is then removed in part by dry etching or the like to form the contact opening 70n, by using, for example, a publicly known lithographic technology. The second upper surface 24b of the n-type semiconductor layer 24 is exposed in the contact opening 70n. Subsequently, the n-side contact electrode 32 is formed on the second upper surface 24b of the n-type semiconductor layer 24 to block the contact opening 70n, by using, for example, a publicly known lithographic technology. After the n-side contact electrode 32 is formed, the n-side contact electrode 32 is annealed. Subsequently, the n-side current diffusion layer 36 that covers the upper surface 32a and the side surface 32b of the n-side contact electrode 32 is formed, by using, for example, a publicly known lithographic technology.

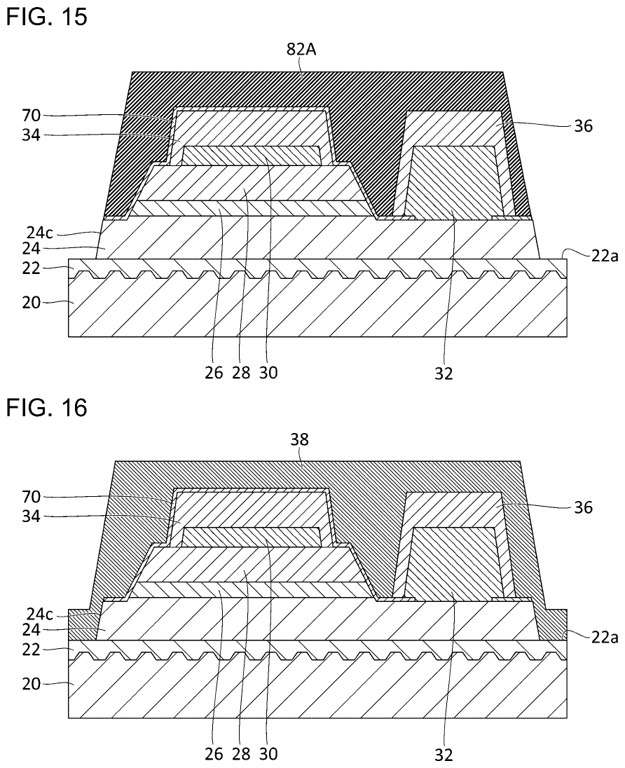

Subsequently, as shown in FIG. 15, a mask 82A is formed on the dielectric covering layer 70 and the n-side current diffusion layer 36 by using, for example, a publicly known lithographic technology. The outer circumferential part of each of the dielectric covering layer 70 and the n-type semiconductor layer 24 in a region not overlapping the mask 82A is removed by dry-etching or the like while the mask 82A is formed, to expose the upper surface 22a of the base layer 22. This etching step forms the side surface 24c of the n-type semiconductor layer 24. The mask 82A is then removed.

Subsequently, as shown in FIG. 16, the first protective layer 38 is formed to cover the entirety of the element from above. The first protective layer 38 is formed to be in contact with and to cover the upper surface 22a of base layer 22, the side surface 24c of the n-type semiconductor layer 24, the n-side current diffusion layer 36, and the dielectric covering layer 70.

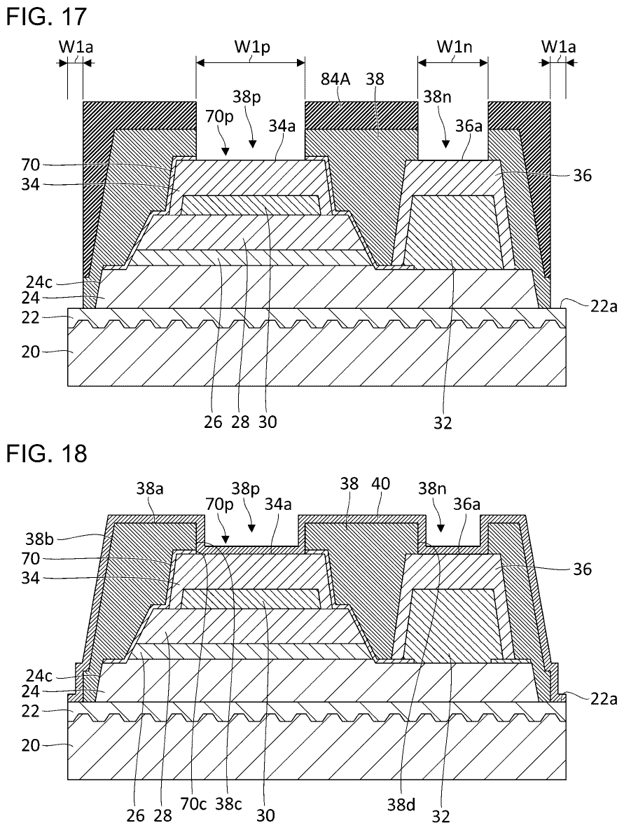

Subsequently, as shown in FIG. 17, a mask 84A is formed on the first protective layer 38 by using, for example, a publicly known lithographic technology. The mask 84A is formed to exclude the range W1p in which the first p-side pad opening 38p is formed, the range W1n in which the first n-side pad opening 38n is formed, and the first outer circumferential range W1a in which the upper surface 22a of the base layer 22 is exposed. The first protective layer 38 and the dielectric covering layer 70 in a region not overlapping the mask 84A are removed by dry-etching or the like while the mask 84A is formed. The first p-side pad opening 38p is formed by removing the first protective layer 38 on the p-side current diffusion layer 34, and the third p-side pad opening 70p is formed by removing the dielectric covering layer 70 on the p-side current diffusion layer 34. This exposes the upper surface 34a of the p-side current diffusion layer 34 in the first p-side pad opening 38p and the third p-side pad opening 70p. The first n-side pad opening 38n in which the upper surface 36a of the n-side current diffusion layer 36 is exposed is formed by removing the first protective layer 38 on the n-side current diffusion layer 36. Further, the upper surface 22a of the base layer 22 is exposed by removing the outer circumferential part of the first protective layer 38 in the first outer circumferential range W1a. The mask 84A is then removed.

Subsequently, as shown in FIG. 18, the second protective layer 40 is formed to cover the entirety of the upper surface of the element structure. The second protective layer 40 can be made of SiNₓ and can be formed by PECVD. The second protective layer 40 is formed to be in contact with and to cover the upper surface 22a of base layer 22 and the upper surface 38a and the side surface 38b of the first protective layer 38. In the first p-side pad opening 38p, the second protective layer 40 is in contact with and covers the inner circumferential surface 38c of the first protective layer 38 that defines the first p-side pad opening 38p, is in contact with and covers the inner circumferential surface 70c of the dielectric covering layer 70 that defines the third p-side pad opening 70p, and is in contact with and covers the upper surface 34a of the p-side current diffusion layer 34. In the first n-side pad opening 38n, the second protective layer 40 is in contact with and covers the inner circumferential surface 38d of the first protective layer 38 that defines the first n-side pad opening 38n and is in contact with and covers the upper surface 36a of the n-side current diffusion layer 36.

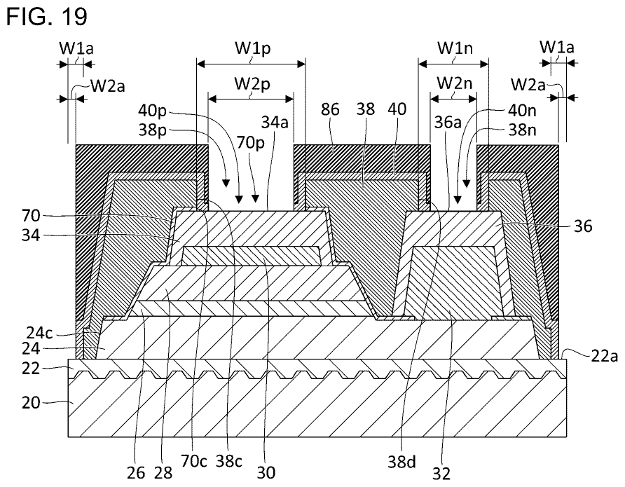

Subsequently, as shown in FIG. 19, a mask 86 is formed on the second protective layer 40. The mask 86 is formed to exclude the range W2p in which the second p-side pad opening 40p is formed, the range W2n in which the second n-side pad opening 40n is formed, and the second outer circumferential range W2a in which the upper surface 22a of the base layer 22 is exposed. The second protective layer 40 in a region not overlapping the mask 86 is removed by dry-etching or the like while the mask 86 is formed. The second p-side pad opening 40p in which the upper surface 34a of the p-side current diffusion layer 34 is exposed is formed by removing the second protective layer 40 on the p-side current diffusion layer 34. The second n-side pad opening 40n in which the upper surface 36a of the n-side current diffusion layer 36 is exposed is formed by removing the second protective layer 40 on the n-side current diffusion layer 36. Further, the upper surface 22a of the base layer 22 is exposed by removing the outer circumferential part of the second protective layer 40 in the second outer circumferential range W2a. The mask 86 is then removed.

Subsequently, as shown in FIG. 11, the p-side pad electrode 42 connected to the p-side current diffusion layer 34 in the second p-side pad opening 40p is formed, and the n-side pad electrode 44 connected to the n-side current diffusion layer 36 in the second n-side pad opening 40n is formed. The p-side pad electrode 42 and the n-side pad electrode 44 can be formed concurrently but can be formed separately.

The semiconductor light-emitting element 10A shown in FIG. 11 is completed through the steps described above.

The second embodiment provides the same advantage as the first embodiment. Further, the semiconductor light-emitting element 10A according to the second embodiment can be used in the CoS type semiconductor light-emitting device 50 shown in FIG. 10. In this case, it is preferred that the range W2p in which the second p-side pad opening 40p is formed be larger than the diameter Dp of the bonding end of the first stud bump 54. Similarly, it is preferred that the range W2n in which the second n-side pad opening 40n is formed be larger than the diameter Dn of the bonding end of the second stud bump 56.

### Third Embodiment

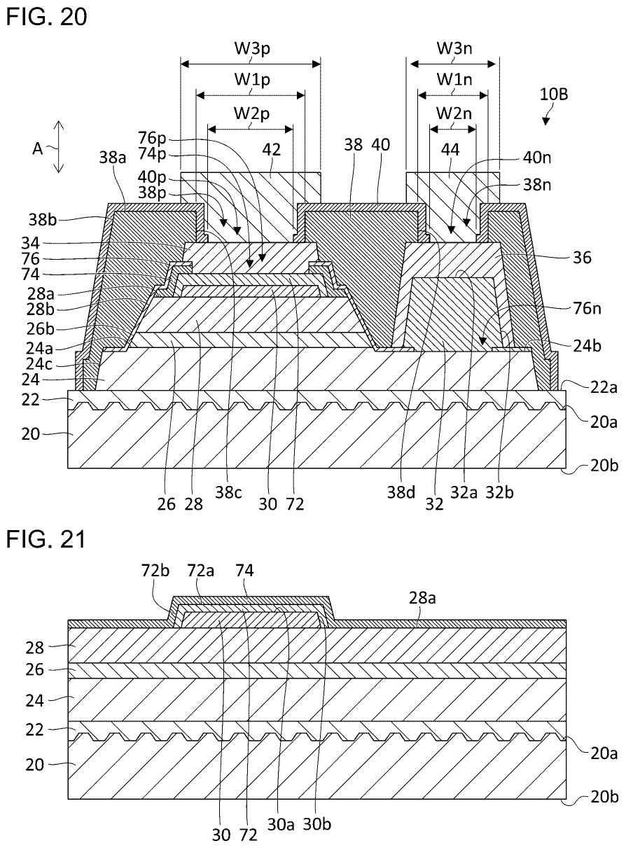

FIG. 20 is a cross-sectional view schematically showing a configuration of a semiconductor light-emitting element 10B according to the third embodiment. The third embodiment differs from the first embodiment in that the semiconductor light-emitting element 10B further includes a p-side electrode covering layer 72, a first dielectric covering layer 74, and a second dielectric covering layer 76. The following description of the third embodiment highlights the difference from the first embodiment. A description of common features is omitted as appropriate.

The semiconductor light-emitting element 10B includes a substrate 20, a base layer 22, an n-type semiconductor layer 24, an active layer 26, a p-type semiconductor layer 28, a p-side contact electrode 30, an n-side contact electrode 32, a p-side current diffusion layer 34, an n-side current diffusion layer 36, a first protective layer 38, a second protective layer 40, a p-side pad electrode 42, an n-side pad electrode 44, a p-side electrode covering layer 72, a first dielectric covering layer 74, and a second dielectric covering layer 76.

The p-side electrode covering layer 72 is provided to be in contact with the upper surface and the side surface of the p-side contact electrode 30 and to cover the entirety of the p-side contact electrode 30. The p-side electrode covering layer 72 includes a Ti layer, an Rh layer, and a TiN layer stacked sequentially. The thickness of the Ti layer of the p-side electrode covering layer 72 is equal to or more than 1 nm and equal to or less than 50 nm and is, for example, equal to or more than 5 nm and equal to or less than nm. The thickness of the Rh layer of the p-side electrode covering layer 72 is equal to or more than 5 nm and equal to or less than 100 nm and is, for example, equal to or more than 10 nm and equal to or less than 50 nm. The TiN layer of the p-side electrode covering layer 72 is made of TiN having conductivity. The thickness of the TiN layer of the p-side electrode covering layer 72 is equal to or more than 5 nm and equal to or less than 100 nm and is, for example, equal to or more than 10 nm and equal to or less than 50 nm.

The first dielectric covering layer 74 is in contact with and covers the upper surface and the side surface of the p-side electrode covering layer 72 and is in contact with and covers the upper surface 28a of the p-type semiconductor layer 28. The first dielectric covering layer 74 has a first connection opening 74p provided on the p-side electrode covering layer 72 and covers the p-side electrode covering layer 72 in a portion different from that of the first connection opening 74p. The first dielectric covering layer 74 is not in contact with the side surface 28b of the p-type semiconductor layer 28 and the side surface 26a of the active layer 26.

The first dielectric covering layer 74 is made of an oxide dielectric material such as SiO₂, Al₂O₃, and HfO₂. The first dielectric covering layer 74 is preferably made of SiO₂. The thickness of the first dielectric covering layer 74 is equal to or more than 50 nm and is, for example, equal to or more than 100 nm and equal to or less than 500 nm.

The second dielectric covering layer 76 is provided between each of the active layer 26 and the p-type semiconductor layer 28 and the first protective layer 38. The second dielectric covering layer 76 is in contact with and covers the second upper surface 24b of the n-type semiconductor layer 24, is in contact with and covers the side surface 26b of the active layer 26, is in contact with and covers the side surface 28b of the p-type semiconductor layer 28, and is in contact with and covers the first dielectric covering layer 74. The second dielectric covering layer 76 has a second connection opening 76p provided on the p-side electrode covering layer 72. The second dielectric covering layer 76 covers the first dielectric covering layer 74 in a portion different from that of the second connection opening 76p. The second connection opening 76p communicates with the first connection opening 74p. The range in which the second connection opening 76p is formed is equal to the range in which the first connection opening 74p is formed. The second dielectric covering layer 76 has a contact opening 76n provided on the second upper surface 24b of the n-type semiconductor layer 24. The second dielectric covering layer 76 covers the second upper surface 24b of the n-type semiconductor layer 24 in a portion different from that of the contact opening 76n.

The second dielectric covering layer 76 is made of an oxide dielectric material such as SiO₂, Al₂O₃, and HfO₂ and is made of a material different from that of the first dielectric covering layer 74. The second dielectric covering layer 76 is preferably made of Al₂O₃. The thickness of the second dielectric covering layer 76 is equal to or more than nm and equal to or less than 100 nm and is, for example, equal to or more than 20 nm and equal to or less than 50 nm.

The n-side contact electrode 32 is provided to block the contact opening 76n and overlaps the second dielectric covering layer 76 outside the contact opening 76n. The n-side contact electrode 32 is in contact with the second dielectric covering layer 76 outside the contact opening 76n. The range in which the n-side contact electrode 32 is formed is larger than a range in which the contact opening 76n is formed.

The p-side current diffusion layer 34 is provided on the p-side electrode covering layer 72 and is connected to the p-side electrode covering layer 72 in the connection openings (the first connection opening 74p and the second connection opening 76p). The p-side current diffusion layer 34 is electrically connected to the p-side contact electrode via the p-side electrode covering layer 72. The p-side current diffusion layer 34 is provided to block the first connection opening 74p and the second connection opening 76p and overlaps the second dielectric covering layer 76 outside the second connection opening 76p. The range in which the A-side current diffusion layer 34 is formed is larger than a range in which the first connection opening 74p and the second connection opening 76p are formed.

The n-side current diffusion layer 36 overlaps the second dielectric covering layer 76 outside the contact opening 76n. The n-side current diffusion layer 36 is in contact with the second dielectric covering layer 76 outside the n-side contact electrode 32. The range in which the n-side current diffusion layer 36 is formed is larger than a range in which the contact opening 76n is formed.

The first protective layer 38 has a first p-side pad opening 38p provided on the p-side current diffusion layer 34 and a first n-side pad opening 38n provided on the n-side current diffusion layer 36. The first protective layer 38 covers the p-side current diffusion layer 34 in a portion different from that of the first p-side pad opening 38p. The first protective layer 38 covers the n-side current diffusion layer 36 in a portion different from that of the first n-side pad opening 38n. The first protective layer 38 is in contact with and covers the dielectric covering layer 70. The first protective layer 38 is in contact with and covers the side surface 24c of the n-type semiconductor layer 24. The first protective layer 38 is in contact with and covers the upper surface 22a of the base layer 22 at the outer circumference of the n-type semiconductor layer 24.

A description will now be given of a method of manufacturing the semiconductor light-emitting element 10B according to the second embodiment. FIGS. 21-27 schematically show steps of manufacturing the semiconductor light-emitting element 10B according to the third embodiment.

First, referring to FIG. 21, the base layer 22, the n-type semiconductor layer 24, the active layer 26, and the p-type semiconductor layer 28 are formed on the first principal surface 20a of the substrate 20 sequentially. Subsequently, the p-side contact electrode 30 is formed on the upper surface 28a of the p-type semiconductor layer 28 by using, for example, a publicly known lithographic technology. After the p-side contact electrode 30 is formed, the p-side contact electrode 30 is annealed.

Subsequently, the p-side electrode covering layer 72 is formed to cover the entirety of the p-side contact electrode 30 by using, for example, a publicly known lithographic technology. The p-side electrode covering layer 72 is in contact with the upper surface 30a and the side surface 30b of the p-side contact electrode 30 and includes a Ti layer, an Rh layer, and a TiN layer stacked sequentially. The p-side electrode covering layer 72 can be formed by sputtering. Subsequently, the first dielectric covering layer 74 is formed to cover the upper surface 28a of the p-type semiconductor layer 28 and to cover the upper surface 72a and the side surface 72b of the p-side electrode covering layer 72. The first dielectric covering layer 74 is made of, for example, SiO₂ and can be formed by PECVD.

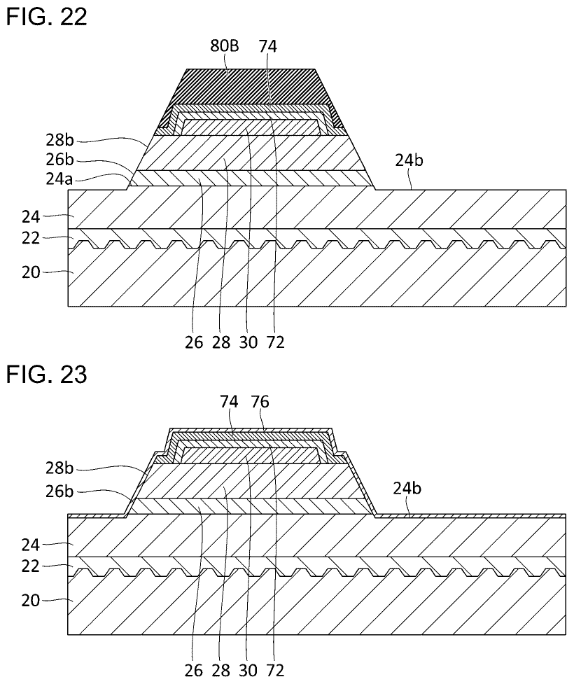

Subsequently, as shown in FIG. 22, a mask 80B is formed on the first dielectric covering layer 74 by using, for example, a publicly known lithographic technology. The mask 80B is formed in a range more extensive than the range in which the p-side contact electrode 30 and the p-side electrode covering layer 72 are formed. After the mask 80B is formed, the first dielectric covering layer 74, the p-type semiconductor layer 28, and the active layer 26 in a region not overlapping the mask 80B are removed by dry-etching or the like to expose the second upper surface 24b of the n-type semiconductor layer 24. This etching step forms the side surface 28b of the p-type semiconductor layer 28, the side surface 26b of the active layer 26, and the second upper surface 24b of the n-type semiconductor layer 24. The mask 80B is then removed.

Subsequently, as shown in FIG. 23, the second dielectric covering layer 76 is formed. The second dielectric covering layer 76 is provided to be in contact with and to cover the second upper surface 24b of the n-type semiconductor layer 24, the side surface 26b of the active layer 26, the side surface 28b of the p-type semiconductor layer 28, and the first dielectric covering layer 74. The second dielectric covering layer 76 is made of, for example, Al₂O₃ and can be formed by ALD.

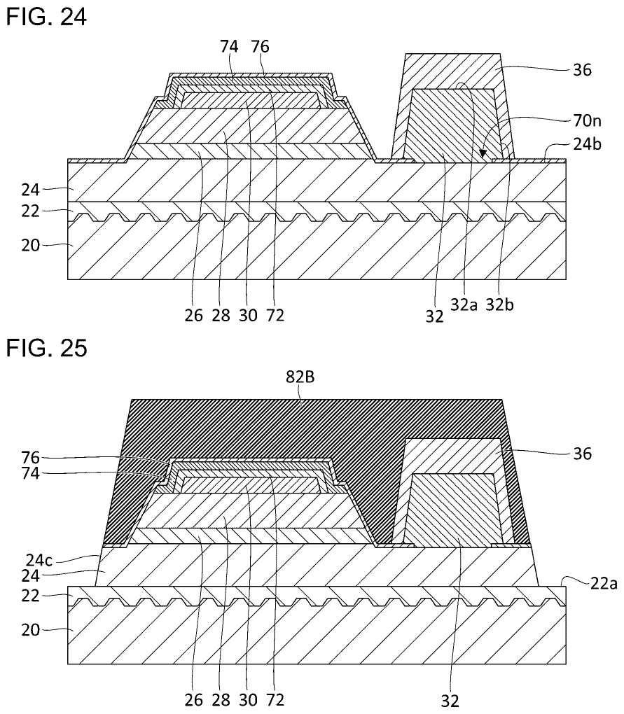

Subsequently, as shown in FIG. 24, the second dielectric covering layer 76 is removed in part by dry-etching or the like by using, for example, a publicly known photolithographic technology to form the contact opening 76n. The second upper surface 24b of the n-type semiconductor layer 24 is exposed in the contact opening 76n. Subsequently, the n-side contact electrode 32 is formed on the second upper surface 24b of the n-type semiconductor layer 24 to block the contact opening 76n, by using, for example, a publicly known lithographic technology. After the n-side contact electrode 32 is formed, the n-side contact electrode 32 is annealed. Subsequently, the n-side current diffusion layer 36 that covers the upper surface 32a and the side surface 32b of the n-side contact electrode 32 is formed, by using, for example, a publicly known lithographic technology.

Subsequently, as shown in FIG. 25, a mask 82B is formed on the second dielectric covering layer 76 and the n-side current diffusion layer 36 by using, for example, a publicly known lithographic technology. The outer circumferential part of each of the second dielectric covering layer 76 and the n-type semiconductor layer 24 in a region not overlapping the mask 82B is removed by dry-etching or the like while the mask 82B is formed, to expose the upper surface 22a of the base layer 22. This etching step forms the side surface 24c of the n-type semiconductor layer 24. The mask 82B is then removed.

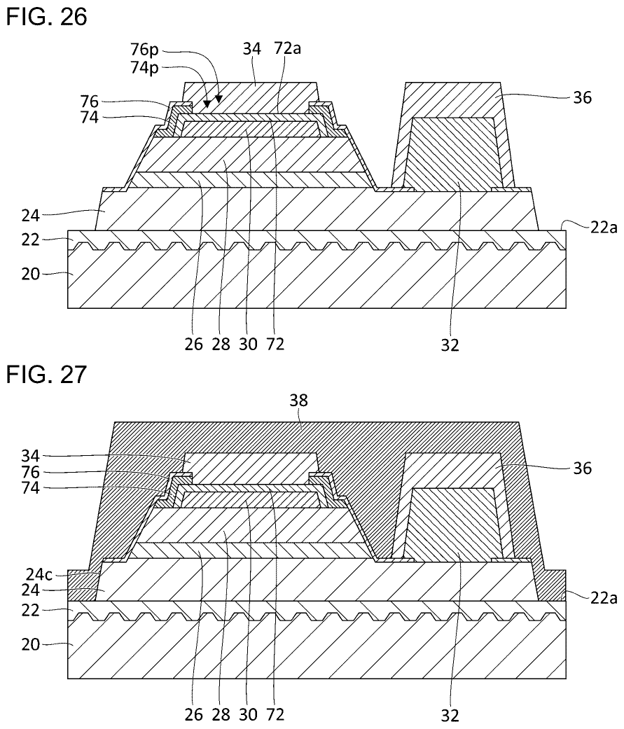

Subsequently, as shown in FIG. 26, the second dielectric covering layer 76 and the first dielectric covering layer 74 are removed in part by dry-etching or the like by using, for example, a publicly known photolithographic technology to form the second connection opening 76p and the first connection opening 74p. This exposes the upper surface 72a of the p-side electrode covering layer 72 in the connection openings (the first connection opening 74p and the second connection opening 76p). Subsequently, the p-side current diffusion layer 34 connected to the p-side electrode covering layer 72 in the connection openings (the first connection opening 74p and the second connection opening 76p) is formed, by using, for example, a publicly known lithographic technology.

Subsequently, as shown in FIG. 27, the first protective layer 38 is formed to cover the entirety of the element from above. The first protective layer 38 is formed to be in contact with and to cover the upper surface 22a of base layer 22, the side surface 24c of the n-type semiconductor layer 24, the second dielectric covering layer 76, the p-side current diffusion layer 34, and the n-side current diffusion layer 36.

The first protective layer 38 in a region not overlapping the mask 84 is removed by dry-etching or the like through a step similar to that of FIG. 7 of the first embodiment. This forms the first p-side pad opening 38p in which the upper surface 34a of the p-side current diffusion layer 34 is exposed, forms the first n-side pad opening 38n in which the upper surface 36a of the n-side current diffusion layer 36 is exposed, and exposes the upper surface 22a of the base layer 22 in the first outer circumferential range W1a.

Subsequently, the second protective layer 40 is formed to cover the entirety of the element from above through a step similar to that of FIG. 8 of the first embodiment. Subsequently, the second protective layer 40 in a region not overlapping the mask 86 is removed by dry-etching or the like through a step similar to that of FIG. 9 of the first embodiment. This forms the second p-side pad opening 40p in which the upper surface 34a of the p-side current diffusion layer 34 is exposed, forms the second n-side pad opening 40n in which the upper surface 36a of the n-side current diffusion layer 36 is exposed, and exposes the upper surface 22a of the base layer 22 in the second outer circumferential range W2a.

Subsequently, as shown in FIG. 20, the p-side pad electrode 42 connected to the p-side current diffusion layer 34 in the second p-side pad opening 40p is formed, and the n-side pad electrode 44 connected to the n-side current diffusion layer 36 in the second n-side pad opening 40n is formed.

The semiconductor light-emitting element 10B shown in FIG. 20 is completed through the steps described above.

The third embodiment provides the same advantage as the first embodiment. Further, the semiconductor light-emitting element 10B according to the third embodiment can be used in the CoS type semiconductor light-emitting device 50 shown in FIG. 10. In this case, it is preferred that the range W2p in which the second p-side pad opening 40p is formed be larger than the diameter Dp of the bonding end of the first stud bump 54. Similarly, it is preferred that the range W2n in which the second n-side pad opening 40n is formed be larger than the diameter Dn of the bonding end of the second stud bump 56.

Described above is an explanation based on exemplary embodiments. The embodiments are intended to be illustrative only and it will be understood by those skilled in the art that various design changes are possible and various modifications are possible and that such modifications are also within the scope of the present invention.

Some modes of the present invention will be described.

The first mode of the present invention is a semiconductor light-emitting element including: a base layer; an n-type semiconductor layer provided on the base layer and made of an n-type AlGaN-based semiconductor material; an active layer provided on the n-type semiconductor layer and made of an AlGaN-based semiconductor material; a p-type semiconductor layer provided on the active layer; an p-side contact electrode that is in contact with an upper surface of the p-type semiconductor layer; an n-side contact electrode that is in contact with an upper surface of the n-type semiconductor layer; a p-side current diffusion layer provided on the p-side contact electrode; an n-side current diffusion layer provided on the n-side contact electrode; a first protective layer including a first p-side pad opening provided on the p-side current diffusion layer and a first n-side pad opening provided on the n-side current diffusion layer, the first protective layer covering the n-type semiconductor layer, the active layer, the p-type semiconductor layer, the p-side contact electrode, the n-side contact electrode, the p-side current diffusion layer, and the n-side current diffusion layer in portions different from portions of the first p-side pad opening and the first n-side pad opening, and the first protective layer being made of silicon oxide; a second protective layer including a second p-side pad opening provided on the p-side current diffusion layer and a second n-side pad opening provided on the n-side current diffusion layer, the second protective layer covering the first protective layer in a portion different from portions of the second p-side pad opening and the second n-side pad opening, the second protective layer covering an inner circumferential surface of the first protective layer that defines the first p-side pad opening, covering an inner circumferential surface of the first protective layer that defines the first n-side pad opening, and the second protective layer being made of silicon nitride; a p-side pad electrode connected to the p-side current diffusion layer in the second p-side pad opening and overlapping the second protective layer outside the second p-side pad opening; and an n-side pad electrode connected to the n-side current diffusion layer in the second n-side pad opening and overlapping the second protective layer outside the second n-side pad opening. According to the first mode, the moisture resistance of the semiconductor light-emitting element can be improved by combining the first protective layer made of silicon oxide and the second protective layer made of silicon nitride. Further, the moisture resistance of the semiconductor light-emitting element can be further improved by covering the inner circumferential surface of the first protective layer that defines the first p-side pad opening and the first n-side pad opening by the second protective layer.

The second mode of the present invention is the semiconductor light-emitting element according to the first mode, wherein the first protective layer is in contact with the base layer at an outer circumference of the n-type semiconductor layer, and the second protective layer is in contact with the base layer at an outer circumference of the first protective layer. According to the second mode, the entirety of the n-type semiconductor layer can be covered by the first protective layer because the first protective layer is in contact with the base layer at the outer circumference of the n-type semiconductor layer. Further, the entirety of the first protective layer can be covered by the second protective layer because the second protective layer is in contact with the base layer at the outer circumference of the first protective layer. This can prevent the first protective layer from being exposed outside at the outer circumference of the first protective layer and further improve the moisture resistance of the semiconductor light-emitting element.

The third mode of the present invention is the semiconductor light-emitting element according to the second mode, wherein each of the p-side pad electrode and the n-side pad electrode is in contact with the second protective layer and is not in contact with the first protective layer. According to the third mode, the p-side pad electrode and the n-side pad electrode can be formed in portions where the second protective layer overlaps the first protective layer. This can increase the quality of sealing in the portions where the p-side pad electrode and the n-side pad electrode are formed and further improve the moisture resistance of the semiconductor light-emitting element.

The fourth mode of the present invention is a method of manufacturing a semiconductor light-emitting element including: forming an n-type semiconductor layer made of an n-type AlGaN-based semiconductor material on a base layer; forming an active layer made of an AlGaN-based semiconductor material on the n-type semiconductor layer; forming a p-type semiconductor layer on the active layer; removing each of the p-type semiconductor layer and the active layer in part to expose an upper surface of the n-type semiconductor layer; forming a p-side contact electrode in contact with an upper surface of the p-type semiconductor layer; forming an n-side contact electrode in contact with an upper surface of the n-type semiconductor layer; forming a p-side current diffusion layer on the p-side contact electrode; forming an n-side current diffusion layer on the n-side contact electrode; forming a first protective layer that covers the n-type semiconductor layer, the active layer, the p-type semiconductor layer, the p-side contact electrode, the n-side contact electrode, the p-side current diffusion layer, and the n-side current diffusion layer and that is made of silicon oxide; removing the first protective layer on the A-side current diffusion layer to form a first p-side pad opening; removing the first protective layer on the n-side current diffusion layer to form a first n-side pad opening; forming a second protective layer that covers the first protective layer, that covers an inner circumferential surface of the first protective layer that defines the first p-side pad opening, covers an inner circumferential surface of the first protective layer that defines the first n-side pad opening, and that is made of silicon nitride; removing the second protective layer on the p-side current diffusion layer to form a second p-side pad opening; removing the second protective layer on the n-side current diffusion layer to form a second n-side pad opening; forming a p-side pad electrode connected to the p-side current diffusion layer in the second p-side pad opening and overlapping the second protective layer outside the second p-side pad opening; and forming an n-side pad electrode connected to the n-side current diffusion layer in the second n-side pad opening and overlapping the second protective layer outside the second n-side pad opening.

The fifth mode of the present invention is the method of manufacturing a semiconductor light-emitting element according to the fourth mode, further including: removing an outer circumferential part of the n-type semiconductor layer to expose an upper surface of the base layer, the first protective layer being formed to be in contact with the upper surface of the base layer at an outer circumference of the n-type semiconductor layer, and removing an outer circumferential part of the first protective layer to expose an upper surface of the base layer, the second protective layer being formed to be in contact with the upper surface of the base layer at an outer circumference of the first protective layer. According to the fifth mode, the entirety of the n-type semiconductor layer can be covered by the first protective layer because the first protective layer is in contact with the base layer at the outer circumference of the n-type semiconductor layer. Further, the entirety of the first protective layer can be covered by the second protective layer because the second protective layer is in contact with the base layer at the outer circumference of the first protective layer. This can prevent the first protective layer from being exposed outside at the outer circumference of the first protective layer and further improve the moisture resistance of the semiconductor light-emitting element.

What is claimed is:

1. A semiconductor light-emitting element comprising:
a base layer;
an n-type semiconductor layer provided on the base layer and made of an n-type AlGaN-based semiconductor material;
an active layer provided on the n-type semiconductor layer and made of an AlGaN-based semiconductor material;
a p-type semiconductor layer provided on the active layer;
an p-side contact electrode that is in contact with an upper surface of the p-type semiconductor layer;
an n-side contact electrode that is in contact with an upper surface of the n-type semiconductor layer;
a p-side current diffusion layer provided on the p-side contact electrode;
an n-side current diffusion layer provided on the n-side contact electrode;
a first protective layer including a first p-side pad opening provided on the p-side current diffusion layer and a first n-side pad opening provided on the n-side current diffusion layer, the first protective layer covering the n-type semiconductor layer, the active layer, the p-type semiconductor layer, the p-side contact electrode, the n-side contact electrode, the p-side current diffusion layer, and the n-side current diffusion layer in portions different from portions of the first p-side pad opening and the first n-side pad opening, and the first protective layer being made of silicon oxide;
a second protective layer including a second p-side pad opening provided on the p-side current diffusion layer and a second n-side pad opening provided on the n-side current diffusion layer, the second protective layer covering the first protective layer in a portion different from portions of the second p-side pad opening and the second n-side pad opening, the second protective layer covering an inner circumferential surface of the first protective layer that defines the first p-side pad opening, covering an inner circumferential surface of the first protective layer that defines the first n-side pad opening, and the second protective layer being made of silicon nitride;
a p-side pad electrode connected to the p-side current diffusion layer in the second p-side pad opening and overlapping the second protective layer outside the second p-side pad opening; and
an n-side pad electrode connected to the n-side current diffusion layer in the second n-side pad opening and overlapping the second protective layer outside the second n-side pad opening.

2. The semiconductor light-emitting element according to claim 1, wherein
the first protective layer is in contact with the base layer at an outer circumference of the n-type semiconductor layer, and
the second protective layer is in contact with the base layer at an outer circumference of the first protective layer.

3. The semiconductor light-emitting element according to claim 1, wherein
each of the p-side pad electrode and the n-side pad electrode is in contact with the second protective layer and is not in contact with the first protective layer.

4. A method of manufacturing a semiconductor light-emitting element comprising:
forming an n-type semiconductor layer made of an n-type AlGaN-based semiconductor material on a base layer;
forming an active layer made of an AlGaN-based semiconductor material on the n-type semiconductor layer;
forming a p-type semiconductor layer on the active layer;
removing each of the p-type semiconductor layer and the active layer in part to expose an upper surface of the n-type semiconductor layer;
forming a p-side contact electrode in contact with an upper surface of the p-type semiconductor layer;
forming an n-side contact electrode in contact with an upper surface of the n-type semiconductor layer;
forming a p-side current diffusion layer on the p-side contact electrode;
forming an n-side current diffusion layer on the n-side contact electrode;
forming a first protective layer that covers the n-type semiconductor layer, the active layer, the p-type semiconductor layer, the p-side contact electrode, the n-side contact electrode, the p-side current diffusion layer, and the n-side current diffusion layer and that is made of silicon oxide;
removing the first protective layer on the p-side current diffusion layer to form a first p-side pad opening;
removing the first protective layer on the n-side current diffusion layer to form a first n-side pad opening;
forming a second protective layer that covers the first protective layer, that covers an inner circumferential surface of the first protective layer that defines the first p-side pad opening, covers an inner circumferential surface of the first protective layer that defines the first n-side pad opening, and that is made of silicon nitride;
removing the second protective layer on the p-side current diffusion layer to form a second p-side pad opening;
removing the second protective layer on the n-side current diffusion layer to form a second n-side pad opening;
forming a p-side pad electrode connected to the p-side current diffusion layer in the second p-side pad opening and overlapping the second protective layer outside the second p-side pad opening; and
forming an n-side pad electrode connected to the n-side current diffusion layer in the second n-side pad opening and overlapping the second protective layer outside the second n-side pad opening.

5. The method of manufacturing a semiconductor light-emitting element according to claim 4, further comprising:
removing an outer circumferential part of the n-type semiconductor layer to expose an upper surface of the base layer, the first protective layer being formed to be in contact with the upper surface of the base layer at an outer circumference of the n-type semiconductor layer, and
removing an outer circumferential part of the first protective layer to expose an upper surface of the base layer, the second protective layer being formed to be in contact with the upper surface of the base layer at an outer circumference of the first protective layer.
